(19) United States
(12) Patent Application Publication
(10) Pub. No.: US 2025/0120021 A1
(43) Pub. Date: Apr. 10, 2025

(54) STRETCHABLE DEVICE

(71) Applicant: Murata Manufacturing Co., Ltd., Nagaokakyo-shi (JP)

(72) Inventor: Tadahiko MATSUMOTO, Nagaokakyo-shi (JP)

(21) Appl. No.: 18/983,614

(22) Filed: Dec. 17, 2024

Related U.S. Application Data
(63) Continuation of application No. PCT/JP2023/021213, filed on Jun. 7, 2023.

(30) Foreign Application Priority Data
Jun. 23, 2022 (JP) 2022-101187

(51) Int. Cl. H05K 5/02

(52) U.S. Cl. CPC H05K 5/02

(57) ABSTRACT

A stretchable device that includes: a stretchable substrate that has a first main surface and a second main surface and is stretchable, wherein the first main surface includes a first region and a second region, and the stretchable substrate is in a folded back configuration such that the first main surface is in an inner side of the stretchable device; and an electronic component on the first main surface of the stretchable substrate.

### CROSS REFERENCE TO RELATED APPLICATIONS

The present application is a continuation of International application No. PCT/JP2023/021213, filed Jun. 7, 2023, which claims priority to Japanese Patent Application No. 2022-101187, filed Jun. 23, 2022, the entire contents of each of which are incorporated herein by reference.

### TECHNICAL FIELD

The present disclosure relates to a stretchable device.

### BACKGROUND ART

There is a conventionally stretchable device described in WO2014/203586 (Patent Document 1). This stretchable device includes a stretchable substrate having a main surface, and an electronic component provided on the stretchable substrate.

Patent Document 1: WO2014/203586

### SUMMARY OF THE DISCLOSURE

A conventional stretchable device as described above is attached, for example, to a body surface of a living body, and used for sensing a biological signal, healing, and treatment. In such uses, moisture of sweat or shower, for example, may intrude into an electronic component to damage the electronic component.

In this regard, an object of the present disclosure is to provide a stretchable device that can protect an electronic component from moisture.

To solve the problem described above, a stretchable device according to one aspect of the present disclosure includes: a stretchable substrate that has a first main surface and a second main surface and is stretchable, wherein the first main surface includes a first region and a second region, and the stretchable substrate is in a folded back configuration such that the first main surface is in an inner side of the stretchable device; and an electronic component on the first main surface of the stretchable substrate.

According to the above aspect, the stretchable substrate is folded back such that the first main surface is in the inner side of the folded stretchable substrate, and the electronic component is disposed in the inner side. This reduces the chances of moisture intruding into the inner side of the stretchable substrate, and thus the electronic component can be protected from moisture.

According to a stretchable device according to one aspect of the present disclosure, an electronic component can be protected from moisture.

### BRIEF EXPLANATION OF THE DRAWINGS

FIG. 1 is a schematic plan view illustrating a first embodiment of a stretchable device.

FIG. 2 is a sectional view taken along II-II of FIG. 1.

FIG. 3 is a sectional view taken along II-II of FIG. 1.

FIG. 4 is a sectional view taken along II-II of FIG. 1.

FIG. 5 is an enlarged view including a first electronic component and the vicinity thereof in FIG. 2.

FIG. 6 is a sectional view illustrating a second embodiment of the stretchable device.

FIG. 7 is a sectional view illustrating a third embodiment of the stretchable device.

FIG. 8 is a sectional view illustrating a fourth embodiment of the stretchable device.

### DESCRIPTION OF THE PREFERRED EMBODIMENTS

Hereinafter, embodiments of the present disclosure will be described in detail with reference to the drawings. Mainly described in each of the embodiments is a point different from points already described before the embodiment. Particularly, similar effects achieved by similar configurations will not be mentioned for each embodiment. Among constituent elements of the embodiments below, a constituent element not described in an independent claim will be described as an optional constituent element. Further, sizes and size-ratios of constituent elements illustrated in the drawings are not necessarily precise. Further, in the drawings, substantially the same configurations are denoted by the same reference symbol, and repeated description may be omitted or simplified.

### First Embodiment

### Schematic Configuration of Stretchable Device 1

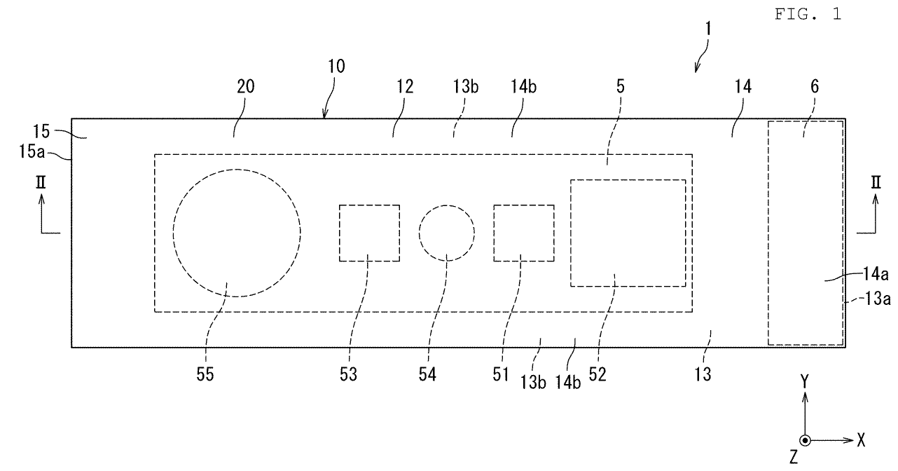

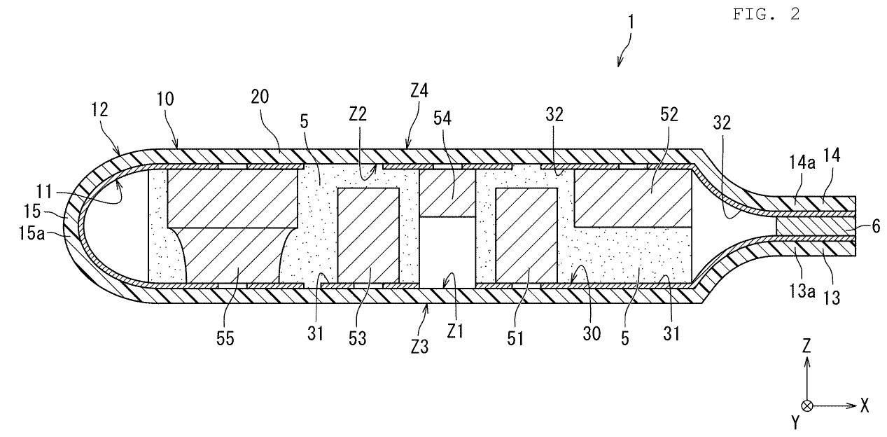

FIG. 1 is a schematic plan view illustrating a first embodiment of a stretchable device 1. FIG. 2 is a sectional view taken along II-II of FIG. 1. As illustrated in FIGS. 1 and 2, a stretchable device 1 includes a stretchable substrate 10 that is stretchable and a plurality of electronic components 51 to 55 provided on the stretchable substrate 10. The stretchable device 1 is, for example, attached to a body surface of a living body, and is used for sensing a biological signal, healing, and treatment. That is, the stretchable device 1 is a biological interface circuit module having flexibility and stretchability.

The meaning of “on the stretchable substrate” is not an absolute direction such as a vertically upward direction defined by the direction of gravitational force but a direction toward the outer side from a surface of the stretchable substrate where the surface is a boundary between the outer side and the inner side of the stretchable substrate. Therefore, “on the stretchable substrate” means a relative position determined by the orientation of a surface of the stretchable substrate. Further, the location expressed by “on” a certain element includes not only a location immediately above and in contact with (on) the element but also a location in the upper side and separated from the element, that is, a location in the upper side of (above) the element with another object interposed therebetween or with a space therebetween.

Hereinafter, as illustrated in the drawings, the direction along a length (longitudinal direction) of the stretchable device 1 is defined as X direction for convenience of description. A width direction of the stretchable device 1 is defined as Y direction. A thickness direction of the stretchable device 1 is defined as Z direction. The X direction, the Y direction, and the Z direction are directions orthogonal to each other, and. The forward Z direction also indicates the upper side in the Z direction, and the reverse Z direction also indicates the lower side in the Z direction.

The stretchable substrate 10 has a first main surface 11 and a second main surface 12. The first main surface 11 includes a first region Z1 and a second region Z2. On each of the first region Z1 and the second region Z2, an electronic component can be mounted, for example, a stretchable wiring connected to an electronic component is provided.

The stretchable substrate 10 is folded back such that the first main surface 11 is in the inner side. In this case, an electronic component can be disposed on the first main surface 11. In one example, the stretchable substrate 10 is folded back such that the first main surface 11 is in the inner side and the first region Z1 and the second region Z2 of the first main surface 11 face each other. In this case, the electronic component can be disposed in at least one of the first region Z1 and the second region Z2.

According to this configuration, the stretchable substrate 10 is folded back such that the first main surface 11 is in the inner side, and the electronic components 51 to 55 can be disposed on the first main surface 11. Therefore, a plurality of electronic components 51 to 55 are disposed in the inner side of the folded stretchable substrate 10. This reduces the chances of moisture intruding into the inner side of the stretchable substrate 10, and thus the plurality of electronic components 51 to 55 can be protected from moisture. Note that the number of electronic components provided may be one. In such a case, one electronic component is disposed in at least one of the first region Z1 and the second region Z2 to be protected from moisture.

When a stretchable substrate is used in an unfolded state, an electronic component disposed on a main surface of the stretchable substrate needs to be wholly sealed with a resin mold to be protected from moisture. As compared with such a case, disposing an electronic component in the inner side of the stretchable substrate 10 does not require a manufacturing process and a manufacturing cost for providing a resin mold.

### Detailed Configuration of Stretchable Device 1

The first main surface 11 of the stretchable substrate 10 has the first region Z1 and the second region Z2. The first region Z1 is on the lower side in the Z direction, and the second region Z2 is on the upper side in the Z direction. The first region Z1 and the second region Z2 are each a flat surface and are disposed parallel to each other.

The meaning of being a flat surface includes not only being a true flat surface but also being a substantially flat surface. For example, when the first region Z1 and the second region Z2 include a wiring, a bulging shape of the wiring is allowed. The meaning of being parallel includes not only being truly parallel but also being substantially parallel. For example, at least one of the first region Z1 and the second region Z2 may be slightly warped. The same applies to the following.

The second main surface 12 of the stretchable substrate 10 has the third region Z3 and the fourth region Z4. The third region Z3 is on the flip side of the first region Z1, and the fourth region Z4 is on the flip side of the second region Z2. The third region Z3 is on the lower side in the Z direction, and the fourth region Z4 is on the upper side in the Z direction. The third region Z3 and the fourth region 24 are each a flat surface and are disposed parallel to each other.

The stretchable substrate 10 has a bent portion 15 that is bent. The bent portion 15 extends along the Y direction and is curved to protrude in the reverse X direction. A vertex 15a of the curve of the bent portion 15 extends in the Y direction. The vertex 15a is at the center in the Z direction of the bent portion 15.

The stretchable substrate 10 has a first end edge 13 on a side including the first region Z1 and a second end edge 14 on another side including the second region Z2. The first end edge 13 constitutes a portion of the entire circumferential end edge of the stretchable substrate 10. The first end edge 13 is located closer to the first region Z1 (third region Z3) than the vertex 15a. The second end edge 14 is a portion of the entire circumferential end edge of the stretchable substrate 10. The second end edge 14 is located closer to the second region Z2 (fourth region Z4) than the vertex 15a.

The first end edge 13 has an end 13a opposing the vertex 15a in the X direction and a side 13b between the vertex 15a and the end 13a. The second end edge 14 has an end 14a opposing the vertex 15a in the X direction and a side 14b between the vertex 15a and the end 14a. The end 13a of the first end edge 13 and the end 14a of the second end edge 14 face each other in the Z direction, and the side 13b of the first end edge 13 and the side 14b of the second end edge 14 face each other in the Z direction. In other words, in a top view, the electronic components 51 to 55 are surrounded by the first end edge 13. This suppresses intrusion of moisture from all directions into the electronic components 51 to 55.

At least a portion of the first end edge 13 and at least a portion of the second end edge 14 are connected via a connection member 6. Specifically, the end 13a of the first end edge 13 and the end 14a of the second end edge 14 are connected via the connection member 6. The connection member 6 is, for example, an anisotropic conductive adhesive, and has conductivity along a thickness direction and insulation across planar directions. The connection member 6 contains a thermosetting epoxy resin and conductive particles contained in the resin.

According to this configuration, at least a portion of the first end edge 13 and at least a portion of the second end edge 14 are connected via the connection member 6, so that the chances of moisture intruding into the inside of the stretchable substrate 10 is further reduced. Note that the side 13b of the first end edge 13 and the side 14b of the second end edge 14 may be connected via the connection member 6.

The stretchable device 1 further includes an elastic member 5 in contact with the first region Z1 and the second region Z2. The elastic member 5 is a member having flexibility and elasticity, and is made of, for example, a sponge material such as polyurethane foam or polyester. According to this configuration, the elastic member 5 is sandwiched between the first region Z1 and the second region Z2 to support the first region Z1 and the second region Z2, so that strength against external pressure can be secured. When the second region Z2 is disposed above the first region Z1 in the direction of gravitational force, the elastic member 5 provided between the first region Z1 and the second region Z2 prevents the second region Z2 from making contact with the first region Z1 also when the second region Z2 is warped by its own weight.

The elastic member 5 covers at least a portion of a plurality of electronic components 51 to 55. Thus, the elastic member 5 can absorb an impact from outside to protect a plurality of electronic components 51 to 55. In addition, the elastic member 5 suppresses intrusion of moisture and can thus protect a plurality of electronic components 51 to 55 from moisture.

The stretchable substrate 10 includes a stretchable element 20 that is stretchable and a stretchable wiring 30 that is provided to the stretchable element 20 and is stretchable. The first main surface 11 has a surface that is a portion of the main surface of the stretchable element 20 not covered by the stretchable wiring 30, and an upper surface of the stretchable wiring 30, the upper surface being on the opposite side of a lower surface that is in contact with the stretchable element 20. The same applies to the first region Z1 and the second region Z2. Note that the stretchable substrate 10 may not include the stretchable wiring 30. In such a case, the first main surface 11 is a main surface of the stretchable element 20.

The stretchable element 20 is a sheet-like or film-like element made of a stretchable resin material, and is two-folded. The resin material is, for example, a styrene resin, an olefin resin, an epoxy resin, a urethane resin, an acrylic resin, or a silicone resin, and is preferably a urethane resin. Examples of urethane resin include thermoplastic polyurethane. Examples of styrene resin include a styrene-butadiene-styrene copolymer resin.

The stretch ratio of the stretchable element 20 is preferably 50% or more. With this stretch ratio, the stretchable device 1 has good conformability to a living body. Young's modulus of the stretchable element 20 is preferably 100 MPa or less, and more preferably 30 MPa or less. This Young's modulus can suppress discomfort felt by a user. Water absorption of the stretchable element 20 is preferably 1% by weight or less from a viewpoint of further securing the reliability of the stretchable device 1. The thickness of the stretchable element 20 is, for example, 0.1 um to 100 μm. The width of the stretchable element 20 is, for example, 10 mm to 100 mm.

The stretchable wiring 30 extends along the main surface of the stretchable element 20. The stretchable wiring 30 may extend not only in one direction in the XY plane but also in a plurality of directions in the XY plane with bends. There are a plurality of stretchable wirings 30. The stretchable wiring 30 may be embedded in the stretchable element 20 such that a portion of the stretchable wiring 30 is exposed on the main surface of the stretchable element 20. The stretchable wiring 30 includes a conductive material having stretchability. The conductive material may be, for example, a metal foil of silver, copper, nickel, or the like, or a mixture of a metal powder of silver, copper, nickel, or the like and an elastomeric resin such as an epoxy resin, a urethane resin, an acrylic resin, and a silicone resin. The metal powder is preferably of silver. In this manner, the stretchable wiring 30 having low resistance can be formed. An average particle D50 of the metal powder is preferably 0.01 μm to 10 μm. Shapes of the metal powder may include a spherical shape, a flat shape, and an irregular shape having a protrusion.

The thickness of the stretchable wiring 30 is preferably 100 μm or less, more preferably 50 μm or less, and preferably 1 μm or more, more preferably 10 μm or more. The stretchable wiring 30 with a thinner thickness has less unevenness which makes lamination and the like easier. The width of the stretchable wiring 30 is preferably 0.2 mm or more.

The stretchable wiring 30 is formed by, for example, screen printing, inkjet printing, or dispensing so as to be in direct contact with the main surface of the stretchable element 20. Note that the stretchable wiring 30 may be disposed on the main surface of the stretchable element 20 with a protective film (not illustrated) having insulation interposed therebetween.

The stretchable wiring 30 includes a first wiring portion 31 provided on a side including the first region Z1 and a second wiring portion 32 provided on another side including the second region Z2. The first wiring portion 31 is a portion of the stretchable wiring 30 located closer to the first region Z1 than the vertex 15a. The second wiring portion 32 is a portion of the stretchable wiring 30 located closer to the second region Z2 than the vertex 15a.

The first wiring portion 31 is electrically connected to the second wiring portion 32. Specifically, the first wiring portion 31 and the second wiring portion 32 are connected via the connection member 6 on a side including the ends 13a and 14a. Meanwhile, the first wiring portion 31 and the second wiring portion 32 are directly connected on another side including the bent portion 15. The first wiring portion 31 and the second wiring portion 32 may be electrically connected either on the side including the ends 13a and 14a or on another side including the bent portion 15.

According to this configuration, since the first wiring portion 31 and the second wiring portion 32 are electrically connected, a more complicated circuit pattern such as that of a multilayer substrate can be configured. In addition, by using an anisotropic conductive adhesive as the connection member 6, the connection member 6 can serve as an electrical connection between the first wiring portion 31 and the second wiring portion 32 as well as a physical connection between the first end edge 13 and the second end edge 14.

A plurality of electronic components 51 to 55 include a first electronic component 51, a second electronic component 52, a third electronic component 53, a fourth electronic component 54, and a fifth electronic component 55. The first electronic component 51 is a temperature sensor that measures a temperature of a living body. The second electronic component 52 is a Bluetooth Low Energy (BLE) module that includes an antenna and performs wireless communication of signals. The third electronic component 53 is an acceleration sensor that measures acceleration of a living body. The fourth electronic component 54 is an LED that measures percutaneous oxygen saturation (SpO2). The fifth electronic component 55 is a battery serving as a power source for operating a circuit. Note that other electronic components such as a coil that emits electromagnetic waves into a body, an ultrasonic oscillator that emits ultrasonic waves into a body, and a light receiving sensor may be included.

A plurality of electronic components 51 to 55 are each disposed on the first region Z1 and the second region Z2. That is, the first electronic component 51 is disposed in the first region Z1, and the second electronic component 52 is disposed in the second region Z2. According to this configuration, in such a use where the third region Z3, which is on the flip side of the first region Z1, of the second main surface 12 of the stretchable substrate 10 is attached to a body surface of a human, the first electronic component 51 is disposed in the first region Z1 and the second electronic component 52 is disposed in the second region Z2, so that the user does not feel discomfort of hardness stemming from the disposed second electronic component 52. Therefore, discomfort felt by a user can be reduced also when the mounting density of electronic components is raised to reduce a dead space on the first main surface 11 of the stretchable substrate 10.

When a plurality of electronic components are disposed on the first main surface 11 of the stretchable substrate 10, a portion of the stretchable substrate 10 where an electronic component is disposed becomes harder than a portion of the stretchable substrate 10 where no electronic component is disposed. In a use where a second main surface of a stretchable substrate in an unfolded state is attached to a body surface of a human as in the related art, the user feels discomfort of hardness stemming from the disposed electronic components. In particular, a portion with a high mounting density of electronic components has a large effect on the user. Meanwhile, increasing the size of a stretchable substrate to reduce the mounting density of electronic components disadvantageously increases a dead space on a first main surface of the stretchable substrate. In addition, a large stretchable substrate limits a place to which the stretchable substrate is attached.

In contrast, in the present embodiment, since the stretchable substrate 10 is bent when used, a plurality of electronic components can be provided also in the second region Z2 on the flip side of the fourth region Z4, which does not contact a human body, to increase the mounting density of electronic components on the first main surface 11. This lowers discomfort felt by a user also when the dead space on the first main surface 11 of the stretchable substrate 10 is small. For example, a small-sized electronic component can be disposed on the side including the first region Z1, and a large-sized electronic component can be disposed on another side including the second region Z2. In addition, since the stretchable substrate 10 is bent when used, the contact area of the stretchable substrate 10 with a body surface is small. This lowers discomfort felt by a user and allows size-adjustment of the stretchable substrate 10 in accordance with a place on a human body where the stretchable substrate is attached.

Similarly, the third electronic component 53 is disposed in the first region Z1, and the fourth electronic component 54 is disposed in the second region Z2. In this configuration, discomfort felt by the user can be suppressed also when the mounting density of electronic components is raised to reduce the dead space on the first main surface 11 of the stretchable substrate 10. The fifth electronic component 55 is disposed so as to be in contact with both the first region Z1 and the second region Z2.

The first electronic component 51, the second electronic component 52, the third electronic component 53, the fourth electronic component 54, and the fifth electronic component 55 are each connected to the stretchable wiring 30. Specifically, the first electronic component 51, the third electronic component 53, and the fifth electronic component 55 are each connected to the first wiring portion 31. The second electronic component 52, the fourth electronic component 54, and the fifth electronic component 55 are each connected to the second wiring portion 32.

The first electronic component 51 and the third electronic component 53 are each an electronic component of a type used in proximity to a body surface. The electronic component of a type used in proximity to a body surface is an electronic component that is preferably disposed close to a body surface. Specifically, a temperature sensor (first electronic component 51) and an acceleration sensor (third electronic component 53) are preferably mounted close to a body surface to measure highly accurate data.

The second electronic component 52 and the fourth electronic component 54 are each an electronic component of a type used remote from a body surface. The electronic component of a type used remote from a body surface is an electronic component that is preferably disposed remote from a body surface. Specifically, an LED (second electronic component 52) has a light emitting unit on a top surface of the component, so that the LED needs to be mounted remote from a body surface with the top surface of the component facing the body surface side. As for a BLE module (fourth electronic component 54), since the human body has a property of absorbing radio waves, mounting the BLE module as far as possible from human skin improves a state of communication.

According to this configuration, in such a use where the third region Z3 on the flip side of the first region Z1 of the second main surface 12 of the stretchable substrate 10 is disposed on a body surface of a human, the first electronic component 51 and the third electronic component 53 are disposed on the side close to the body surface, and the second electronic component 52 and the fourth electronic component 54 are disposed on the side remote from the body surface.

The first electronic component 51 and the second electronic component 52 do not overlap in a direction orthogonal to the first region Z1. The direction orthogonal to the first region Z1 coincides with the Z direction. According to this configuration, the first electronic component 51 and the second electronic component 52 do not interfere with each other in a direction orthogonal to the first region Z1. This allows bringing the first region Z1 and the second region Z2 closer to each other to reduce the thickness of the stretchable device 1.

Similarly, the first electronic component 51 and the fourth electronic component 54 do not overlap in a direction orthogonal to the first region Z1. The second electronic component 52 and the third electronic component 53 do not overlap in a direction orthogonal to the first region Z1. The third electronic component 53 and the fourth electronic component 54 do not overlap in a direction orthogonal to the first region Z1. The fifth electronic component 55 does not overlap the first to fourth electronic components 51 to 54 in a direction orthogonal to the first region Z1.

Note that electronic components may overlap in a view in a direction orthogonal to the first region Z1, and in this case, the plane area of the stretchable element 20 when viewed in a direction orthogonal to the first region Z1 can be further reduced. The elastic member 5 is preferably provided between an upper and a lower electronic components to suppress interference between the upper and the lower electronic components.

The first electronic component 51 and the second electronic component 52 overlap in a direction parallel to the first region Z1. The direction parallel to the first region Z1 coincides with a direction along the XY plane. According to this configuration, the first electronic component 51 and the second electronic component 52 can be disposed so as not to interfere with each other in a direction orthogonal to the first region Z1. This allows bringing the first region Z1 and the second region Z2 closer to each other to reduce the thickness of the stretchable device 1.

Similarly, the first electronic component 51 and the fourth electronic component 54 overlap in a direction parallel to the first region Z1. The second electronic component 52 and the third electronic component 53 overlap in a direction parallel to the first region Z1. The third electronic component 53 and the fourth electronic component 54 overlap in a direction parallel to the first region Z1. The fifth electronic component 55 overlap the first to fourth electronic components 51 to 54 in a direction parallel to the first region Z1. Note that electronic components may not overlap in a direction parallel to the first region Z1.

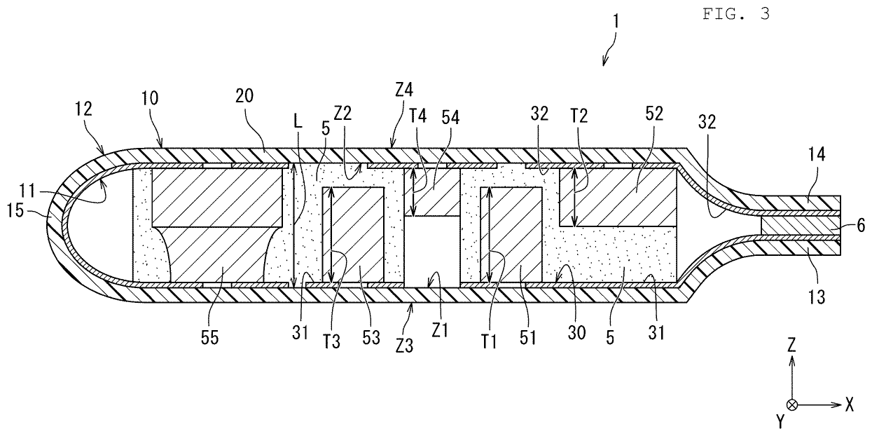

FIG. 3 is a sectional view taken along II-II of FIG. 1. As illustrated in FIG. 3, the sum of a first thickness T1 of the first electronic component 51 and a second thickness T2 of the second electronic component 52 is larger than a longest distance L between the first region Z1 and the second region Z2. The thickness is a size in a direction orthogonal to the first region Z1, and the longest distance is the largest size in the direction orthogonal to the first region Z1. According to this configuration, the first electronic component 51 and the second electronic component 52 can be disposed so as not to interfere with each other in a direction orthogonal to the first region Z1. This allows bringing the first region Z1 and the second region Z2 closer to each other to reduce the thickness of the stretchable device 1.

Similarly, the sum of the first thickness T1 of the first electronic component 51 and a fourth thickness T4 of the fourth electronic component 54 is larger than the longest distance L. The sum of the second thickness T2 of the second electronic component 52 and a third thickness T3 of the third electronic component 53 is larger than the longest distance L. The sum of the third thickness T3 of the third electronic component 53 and the fourth thickness T4 of the fourth electronic component 54 is larger than the longest distance L. Note that the sum of the thicknesses of a set of upper and lower electronic components may be smaller than the longest distance L.

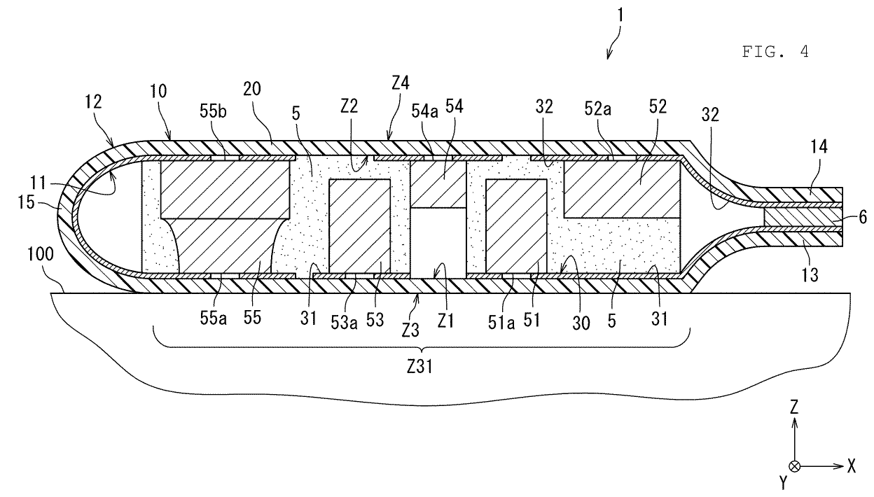

FIG. 4 is a sectional view taken along II-II of FIG. 1. As illustrated in FIG. 4, the third region Z3 of the second main surface 12 of the stretchable substrate 10 has a body surface region Z31 that can be brought into contact with a body surface 100. The body surface 100 is a skin of a human body. The total area of mounting surfaces of a plurality of electronic components 51 to 55 disposed in the first region Z1 and the second region Z2 is larger than the area of the body surface region Z31. The mounting surface is not limited to a surface by which an electronic component makes direct contact with the stretchable substrate 10, and includes a surface of an electronic device disposed at the stretchable substrate 10, which surface facing the stretchable substrate 10.

Specifically, a mounting surface 51a of the first electronic component 51 is a surface facing the first region Z1. A mounting surface 52a of the second electronic component 52 is a surface facing the second region Z2. A mounting surface 53a of the third electronic component 53 is a surface facing the first region Z1. A mounting surface 54a of the fourth electronic component 54 is a surface facing the second region Z2. A first mounting surface 55a of the fifth electronic component 55 is a surface facing the first region Z1, and a second mounting surface 55b of the fifth electronic component 55 is a surface facing the second region Z2. The total area of the mounting surfaces 51a, 52a, 53a, 54a, 55a, and 55b is larger than the area of the body surface region Z31.

According to this configuration, more electronic components can be disposed than on the body surface region Z31, so that a large number electronic components can be mounted with a smaller mounting surface of the stretchable device 1 on the body surface 100.

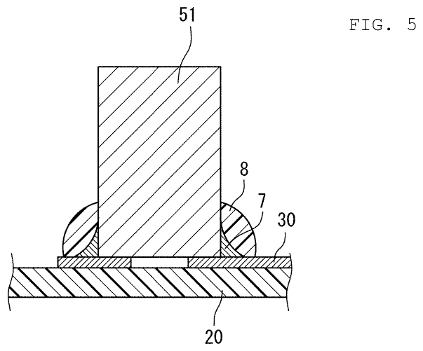

FIG. 5 is an enlarged view including the first electronic component 51 and the vicinity thereof in FIG. 2. As illustrated in FIG. 5, the first electronic component 51 is connected to the stretchable wiring 30 via a joint portion 7. The joint portion 7 is, for example, a conductive material such as solder. The joint portion 7 is covered with a covering portion 8. The covering portion 8 is, for example, a resin such as a thermosetting epoxy resin. This configuration protects the joint portion 7 from mechanical stress due to stretch and contraction of the stretchable substrate 10 (the stretchable element 20 and the stretchable wiring 30).

### Method of Manufacturing Stretchable Device 1

A method of manufacturing the stretchable device 1 will be described with reference to FIG. 2.

First, the stretchable substrate 10 is unfolded into a sheet form, and a plurality of electronic components 51 to 55 are each disposed in the corresponding one of the first region Z1 and the second region Z2 on the first main surface 11 of the stretchable substrate 10. The elastic member 5 is provided to at least one of the first region Z1 and the second region Z2.

Then, the stretchable substrate 10 is two-folded such that the first main surface 11 is in the inner side. As one example, the stretchable substrate 10 is folded back such that the first main surface 11 is in the inner side and the first region Z1 and the second region Z2 of the first main surface 11 face each other. With this fold, the electronic components 51 and 53 disposed in the first region Z1 and the electronic components 52 and 54 disposed in the second region Z2 do not interfere with each other in a direction orthogonal to the first region Z1.

Then, the end 13a of the first end edge 13 and the end 14a of the second end edge 14 are connected by the connection member 6, and the end 13a of the first end edge 13 and the end 14a of the second end edge 14 are sealed. The stretchable device 1 is manufactured in this manner.

### Second Embodiment

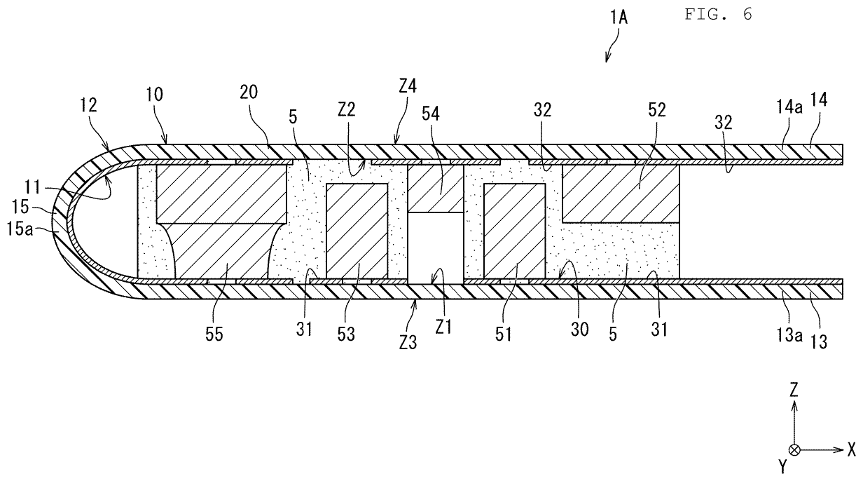

FIG. 6 is a sectional view illustrating a second embodiment of the stretchable device. FIG. 6 is a drawing corresponding to a section taken along II-II of FIG. 1. The second embodiment is different from the first embodiment in that a connection member is not provided. This different configuration will be described below. Other configurations are the same as those of the first embodiment and are each denoted by the same reference symbol as the corresponding one of the first embodiment to omit the description thereof.

As illustrated in FIG. 6, a stretchable device 1A of the second embodiment is not provided with the connection member 6 of the first embodiment. That is, the first end edge 13 and the second end edge 14 are not connected and are separated. Specifically, the end 13a of the first end edge 13 and the end 14a of the second end edge 14 are separated.

According to this configuration, another component (not illustrated) can be inserted in the space between the first end edge 13 and the second end edge 14 to allow easy electrical connection of another component to a stretchable wiring 30 of the stretchable device 1A.

Further in the stretchable device 1A of the second embodiment, an elastic member 5 may not be provided. In the stretchable device 1A of the second embodiment, a connection member 6 may be provided without providing the elastic member 5.

### Third embodiment

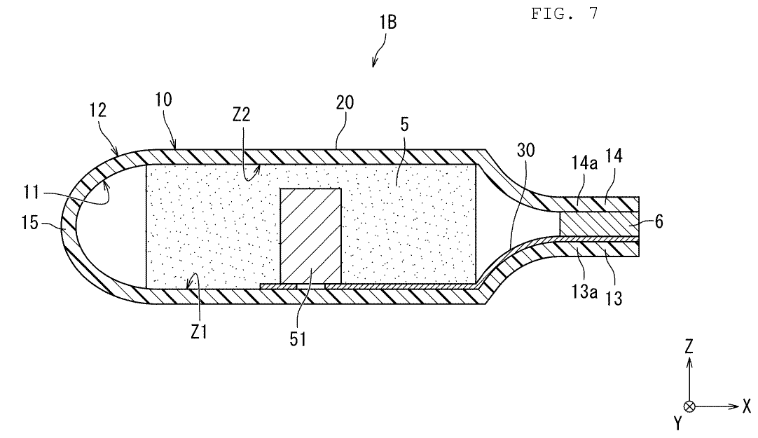

FIG. 7 is a sectional view illustrating a third embodiment of the stretchable device. FIG. 7 corresponds to a section taken along II-II of FIG. 1. The third embodiment is different from the first embodiment in the number of electronic components. This different configuration will be described below. Other configurations are the same as those of the first embodiment and are each denoted by the same reference symbol as the corresponding one of the first embodiment to omit the description thereof.

As illustrated in FIG. 7, a stretchable device 1B of the third embodiment includes one electronic component disposed in at least one of a first region Z1 and a second region Z2. Specifically, a first electronic component 51 is disposed in the first region Z1. Note that the first electronic component 51 may be any one of the electronic components 51 to 55 described as examples herein.

According to this configuration, the first electronic component 51 is disposed in the inner side of a folded stretchable substrate 10. This configuration reduces the chances of moisture intruding into the inner side of the stretchable substrate 10, and thus the first electronic component 51 can be protected from moisture. The one electronic component may be disposed not in the first region Z1 but in the second region Z2, or may be disposed to be in contact with both the first region Z1 and the second region Z2.

### Fourth Embodiment

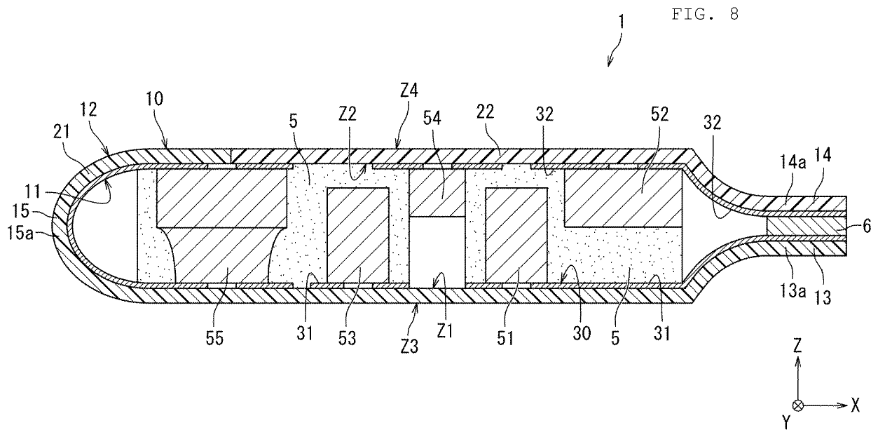

FIG. 8 is a sectional view illustrating a fourth embodiment of the stretchable device. FIG. 8 corresponds to a section taken along II-II of FIG. 1. The fourth embodiment is different from the first embodiment in that a plurality of types of element is used. This different configuration will be described below. Other configurations are the same as those of the first embodiment and are each denoted by the same reference symbol as the corresponding one of the first embodiment to omit the description thereof.

As already described, the stretchable element 20 in the first embodiment is two-folded as a whole. The stretchable element 20 having the folded structure has a single continuous form or a continuous form of a single type.

Meanwhile, in the fourth embodiment, a stretchable composite element that includes a plurality of types of element taking a continuous form and has a folded structure as a whole can be configured. As one example, as illustrated in FIG. 8, a first stretchable element 21 and a second element 22 made of different materials are connected to be continuous along the longitudinally extending direction. In the form illustrated in FIG. 8, as one example, the second element 22 constituting a portion of the stretchable composite element having the folded structure is on a relatively upper side, and the most of the first stretchable element 21 is on a relatively lower side, and both the elements are continuous.

As illustrated in FIG. 8, when the second element 22 does not include a curved portion formed by folding, the second element 22 may be an element that does not have elasticity. Specifically, the second element 22 may be a rigid substrate or a flexible printed circuit (FPC). It goes without saying that the second element 22 may have stretchability. When the second element 22 has stretchability, the second element 22 may include a curved portion.

Materials of the first stretchable element 21 and the second element 22 (when having stretchability) may be similar to those that can be used for the stretchable element 20 described in the first embodiment. For example, the material of the first stretchable element 21 may be a type of resin material selected from the group consisting of styrene resins, olefin resins, epoxy resins, urethane resins, acrylic resins, and silicone resins, and the material of the second element 22 (when having elasticity) may be a material different from the material used for the first stretchable element 21.

Note that the present disclosure is not limited to the above-described embodiments, and can be changed in design without departing from the gist of the present disclosure. For example, the respective features of the first to fourth embodiments may be combined in a various manner.

<1> A stretchable device including: a stretchable substrate that has a first main surface and a second main surface and is stretchable, wherein the first main surface includes a first region and a second region, and the stretchable substrate is in a folded back configuration such that the first main surface is in an inner side of the stretchable device; and an electronic component on the first main surface of the stretchable substrate.

<2> The stretchable device according to <1>, wherein the electronic component is one of a plurality of electronic components, and the plurality of electronic components are each in at least one of the first region and the second region.

<3> The stretchable device according to <1>or <2>, wherein the stretchable substrate has a first end edge on a first side thereof including the first region and a second end edge on a second side thereof including the second region, and the stretchable device further comprises a connection member that connects at least a portion of the first end edge and at least a portion of the second end edge to each other.

<4> The stretchable device according to any one of <1> to <3>, wherein the stretchable substrate includes a stretchable element that is stretchable and a stretchable wiring that is on the stretchable element and is stretchable, the stretchable wiring includes a first wiring portion on a first side thereof including the first region and a second wiring portion on a second side thereof including the second region, and the first wiring portion and the second wiring portion are electrically connected.

<5> The stretchable device according to any one of <1> to <4>, further including an elastic member that is in contact with the first region and the second region.

<6> The stretchable device according to any one of <1> to <5>, wherein the electronic component is one of a plurality of electronic components, the plurality of electronic components include a first electronic component and a second electronic component, and the first electronic component is in the first region, and the second electronic component is in the second region.

<7> The stretchable device according to <6>, wherein the first electronic component is an electronic component of a type used in proximity to a body surface, and the second electronic component is an electronic component of a type used remote from a body surface.

<8> The stretchable device according to <6>or <7>, wherein the first electronic component and the second electronic component do not overlap in a direction orthogonal to the first region.

<9> The stretchable device according to any one of <6> to <8>, wherein a sum of a thickness of the first electronic component and a thickness of the second electronic component is larger than a longest distance between the first region and the second region.

<10> The stretchable device according to any one of <6> to <9>, wherein the first electronic component and the second electronic component overlap in a direction parallel to the first region.

<11> The stretchable device according to any one of <1> to <3>, wherein the electronic component is one of a plurality of electronic components, the plurality of electronic components are on the first region and the second region, the second main surface has a third region on a flip side of the first region, and the third region has a body surface region configured to be brought into contact with a body surface, and a total area of mounting surfaces of the plurality of electronic components on the first region and the second region is larger than an area of the body surface region.

### DESCRIPTION OF REFERENCE SYMBOLS

1, 1A, 1B: Stretchable device
5: Elastic member
6: Connection member
10: Stretchable substrate
11: First main surface
12: Second main surface
13: First end edge
14: Second end edge
15: Bent portion
15a: Vertex
20: Stretchable element
21: First stretchable element
22: Second stretchable element
30: Stretchable wiring
31, 32: First and second wiring portions
51, 52, 53, 54, 55: First, second, third, fourth, and fifth electronic components
51a, 52a, 53a, 54a, 55a, 55b: Mounting surface
100: Body surface
Z1, Z2, Z3, Z4: First, second, third, and fourth regions
Z31: Body surface region
L: Longest distance
T1, T2, T3, T4: First, second, third, and fourth thicknesses

1. A stretchable device comprising:
a stretchable substrate that has a first main surface and a second main surface and is stretchable, wherein the first main surface includes a first region and a second region, and the stretchable substrate is in a folded back configuration such that the first main surface is in an inner side of the stretchable device; and
an electronic component on the first main surface of the stretchable substrate.

2. The stretchable device according to claim 1, wherein the stretchable substrate is in the folded back configuration such that the first region and the second region face each other, and the electronic component is in at least one of the first region and the second region.

3. The stretchable device according to claim 2, wherein
the electronic component is one of a plurality of electronic components, and
the plurality of electronic components are each in at least one of the first region and the second region.

4. The stretchable device according to claim 1, wherein the stretchable substrate has a first end edge on a first side thereof including the first region and a second end edge on a second side thereof including the second region, and the stretchable device further comprises a connection member that connects at least a portion of the first end edge and at least a portion of the second end edge to each other.

5. The stretchable device according to claim 4, wherein the connection member is an anisotropic conductive adhesive that has conductivity along a thickness direction and insulation across planar directions thereof.

6. The stretchable device according to claim 1, wherein
the stretchable substrate includes a stretchable element that is stretchable and a stretchable wiring that is on the stretchable element and is stretchable,
the stretchable wiring includes a first wiring portion on a first side thereof including the first region and a second wiring portion on a second side thereof including the second region, and
the first wiring portion and the second wiring portion are electrically connected.

7. The stretchable device according to claim 6, wherein a stretch ratio of the stretchable element is 50% or more.

8. The stretchable device according to claim 6, wherein a Young's modulus of the stretchable element is 100 MPa or less.

9. The stretchable device according to claim 1, further comprising an elastic member that is in contact with the first region and the second region.

10. The stretchable device according to claim 1, wherein
the electronic component is one of a plurality of electronic components,
the plurality of electronic components include a first electronic component and a second electronic component, and
the first electronic component is in the first region, and the second electronic component is in the second region.

11. The stretchable device according to claim 10, wherein
the first electronic component is an electronic component constructed for use in proximity to a body surface, and
the second electronic component is an electronic component constructed for use remote from the body surface.

12. The stretchable device according to claim 10, wherein the first electronic component and the second electronic component do not overlap in a direction orthogonal to the first region.

13. The stretchable device according to claim 10, wherein a sum of a thickness of the first electronic component and a thickness of the second electronic component is larger than a longest distance between the first region and the second region.

14. The stretchable device according to claim 10, wherein the first electronic component and the second electronic component overlap in a direction parallel to the first region.

15. The stretchable device according to claim 1, wherein
the electronic component is one of a plurality of electronic components,
the plurality of electronic components are on the first region and the second region,
the second main surface has a third region on a flip side of the first region, and the third region has a body surface region configured for contact with a body surface, and
a total area of mounting surfaces of the plurality of electronic components on the first region and the second region is larger than an area of the body surface region.

16. The stretchable device according to claim 1, wherein the stretchable substrate has a first end edge on a first side thereof including the first region and a second end edge on a second side thereof including the second region, and the first end edge and the second end edge are not connected and are separated from each other.

17. The stretchable device according to claim 16, further comprising an elastic member that is in contact with the first region and the second region.
